(19) United States
(12) Patent Application Publication
(10) Pub. No.: US 2025/0040398 A1
(43) Pub. Date: Jan. 30, 2025

(54) Optic for an Under-Display Image Sensor of an Electronic Device

(71) Applicant: Google LLC, Mountain View, CA (US)

(72) Inventors: Choongho Lee, San Diego, CA (US); Triton Hurd, Encinitas, CA (US)

(21) Appl. No.: 18/716,691

(22) PCT Filed: Dec. 6, 2021
(86) PCT No.: PCT/US2021/061953

§ 371 Date: Jun. 5, 2024

(51) Int. Cl. H10K 59/65; G04G 17/04; G06F 1/16; H01L 27/146; H10K 59/80

(52) U.S. Cl. CPC H10K 59/65; G04G 17/045; G06F 1/163; G06F 1/1686; H01L 27/14627; H10K 59/879

(57) ABSTRACT

An electronic device is provided. The electronic device includes a display having a plurality of pixels. The display defines a transparent region positioned between a first pixel of the plurality of pixels and a second pixel of the plurality of pixels. The electronic device includes an image sensor positioned underneath the display. The image sensor is aligned with the transparent region defined by the display. The electronic device further includes an optic positioned on the display and over the transparent region defined by the display. The optic is configured to direct external light into the transparent region of the display.

### FIELD

The present disclosure relates generally to displays for electronic devices having an under-display image sensor. More particularly, the present disclosure relates to an optic for the under-display image sensor.

### BACKGROUND

Electronic devices (e.g., smartphones, laptop, smartwatches, tablets, etc.) can include a display to display content (e.g., time, date, etc.) to a user. Electronic devices can further include one or more cameras. For instance, electronic devices can include an under-display camera. The under-display camera can be configured to obtain image data. For instance, the under-display camera can capture image data (e.g., video, photos) of a user using the electronic device.

### SUMMARY

Aspects and advantages of embodiments of the present disclosure will be set forth in part in the following description, or can be learned from the description, or can be learned through practice of the embodiments.

In one aspect, an electronic device is provided. The electronic device includes a display having a plurality of pixels. The display defines a transparent region positioned between a first pixel of the plurality of pixels and a second pixel of the plurality of pixels. The electronic device includes an image sensor positioned underneath the display. The image sensor is aligned with the transparent region defined by the display. The electronic device further includes an optic positioned on the display and over the transparent region defined by the display. The optic is configured to direct external light into the transparent region of the display.

In some implementations, the transparent region includes an aperture extending from the image sensor to a top portion of the display along a vertical direction. In some implementations, the plurality of pixels are arranged in a plurality of rows. Furthermore, in such implementations, the first pixel and the second pixel are next to one another in a first row of the plurality of rows. In some implementations, the optic comprises a lens having a diameter of less than 1 millimeter.

In some implementations, the optic is disposed on a top portion of the display. Furthermore, in some implementations, the top portion of the display includes a thin film encapsulation layer. In some implementations, a shape of the optic corresponds to a dome. In alternative implementations, a cross-sectional shape of the optic corresponds to a triangle.

In some implementations, the display includes a plurality of additional optics disposed on the display. Furthermore, each of the plurality of additional optics can be positioned over a corresponding pixel of the plurality of pixels. In some implementations, the optic positioned over the transparent region of the display can have a first shape, whereas one or more of the additional optics can have a second shape that is different from the first shape. In some implementations, one or more of the additional optics includes a lens having a diameter of less than 1 millimeter. In some implementations, the optic positioned over the transparent region and the plurality of additional optics are integrally formed as a monolithic structure.

In another aspect, a wearable computing device is provided. The wearable computing device includes a housing, a first band, and a second band. The first band is coupled to the housing at a first location. The second band is coupled to the housing at a second location. Furthermore, the second band is couplable to the first band. The wearable computing device includes a display having a plurality of pixels. The display defines a transparent region positioned between a first pixel of the plurality of pixels and a second pixel of the plurality of pixels. The electronic device includes an image sensor positioned underneath the display. The image sensor is aligned with the transparent region defined by the display. The electronic device further includes an optic positioned on the display and over the transparent region defined by the display. The optic is configured to direct external light into the transparent region of the display.

In some implementations, the plurality of pixels are arranged in a plurality of rows. Furthermore, the first pixel and the second pixel are next to one another in a first row of the plurality of rows. In some implementations, the optic is disposed on a top portion of the display. Furthermore, in some implementations, the top portion of the display includes a thin film encapsulation layer.

In some implementations, the wearable computing device further includes a plurality of additional optics disposed on the display. Furthermore, each of the plurality of additional optics can be positioned over a corresponding pixel of the plurality of pixels. In some implementations, the optic positioned over the transparent region of the display can have a first shape, whereas one or more of the additional optics can have a second shape that is different from the first shape. In some implementations, one or more of the additional optics includes a lens having a diameter of less than 1 millimeter. In some implementations, the optic positioned over the transparent region and the plurality of additional optics are integrally formed as a monolithic structure.

These and other features, aspects, and advantages of various embodiments of the present disclosure will become better understood with reference to the following description and appended claims. The accompanying drawings, which are incorporated in and constitute a part of this specification, illustrate example embodiments of the present disclosure and, together with the description, serve to explain the related principles.

### BRIEF DESCRIPTION OF THE DRAWINGS

Detailed discussion of embodiments directed to one of ordinary skill in the art is set forth in the specification, which makes reference to the appended figures, in which:

FIG. 1 depicts an electronic device according to some implementations of the present disclosure.

FIG. 2 depicts a cross-sectional view of a display of an electronic device according to some implementations of the present disclosure.

FIG. 3 depicts a side view of an optic disposed on a display of an electronic device according to some implementations of the present disclosure.

FIG. 4 depicts a wearable computing device according to some implementations of the present disclosure.

FIG. 5 depicts an exploded view of a wearable computing device according to some implementations of the present disclosure.

FIG. 6 depicts a cross-sectional view of a wearable computing device according to some implementations of the present disclosure.

### DETAILED DESCRIPTION

Reference now will be made in detail to embodiments of the present disclosure, one or more examples of which are illustrated in the drawings. Each example is provided by way of explanation of the present disclosure, not limitation of the present disclosure. In fact, it will be apparent to those skilled in the art that various modifications and variations can be made in the present disclosure without departing from the scope or spirit of the disclosure. For instance, features illustrated or described as part of one embodiment can be used with another embodiment to yield a still further embodiment. Thus, it is intended that the present invention covers such modifications and variations as come within the scope of the appended claims and their equivalents.

Example aspects of the present disclosure are directed to electronic devices (e.g., smartphones, laptops, smartwatches, tablets, etc.) having a display (e.g., organic light emitting diode display) configured to display content (e.g., emails, text messages. The electronic device can further include an image sensor (e.g., camera) positioned underneath the display. In this manner, the image sensor can be referred to as an under-display image sensor.

The under-display image sensor receives less external light (e.g., light from an environment surrounding the electronic device) compared to, for instance, an image sensor that is not positioned underneath the display. As such, the quality of images obtained via the under-display image sensor can be inferior compared to the quality of images obtained using the other image sensor of the electronic device. For example, images obtained via the under-display image sensor can be blurrier compared to images obtained via the image sensor that is not positioned underneath the display.

Example aspects of the present disclosure are directed to an electronic device having a display defining a transparent region defined between adjacent pixels of the display. For instance, the transparent region can be defined between adjacent pixels in a row of pixels. It should be understood that no pixels are included in the transparent region of the display. In some implementations, the transparent region can be an aperture defined between the under-display image sensor and a top portion (e.g., thin encapsulation layer) of the display. More particularly, the aperture can extend from the top portion of the display to the image sensor. In this manner, the display can provide a dedicated path (e.g., aperture) for external light passing through the top portion of the display to be directed onto the under-display image sensor.

The electronic device can further include an optic positioned over the transparent region of the display to direct external light into the transparent region (e.g., aperture) defined by the display. For instance, in some implementations, the optic can be positioned on the top portion (e.g., thin film encapsulation layer) of the display. It should be understood that one or more parameters (e.g., shape) of the optic can be configured to direct (e.g., refract) the external light into the transparent region of the display. For instance, in some implementations, the optic can have a dome shape. In alternative implementations, the optic can have a shape corresponding to a triangle. More particularly, a cross-sectional shape of the optic can correspond to a triangle. In some implementations, the optic can include a micro lens. As used herein, a “micro lens” refers to a lens having a diameter that is less than 1 millimeter.

In some implementations, the electronic device can include a plurality of additional optics. Each of the additional optics can be positioned over a corresponding pixel of the plurality of pixels included in the display. Furthermore, each of the additional optics can be configured to direct light emitted from the corresponding pixel into the environment surrounding the electronic device. For instance, parameters (e.g., shape, refractive index) of each of the additional optics can be configured to focus light emitted from the corresponding pixel. In this manner, a “screen-door” effect associated with the display can be reduced or eliminated.

In some implementations, the optic positioned over the transparent region of the display and the plurality of additional optics positioned over corresponding pixels of the display can be integrally formed as a monolithic structure. For instance, in such implementations, the monolithic structure can be positioned on the top portion (e.g., thin film encapsulation layer) of the display. In this manner, the optic can be aligned with the transparent region of the display and the additional optics can be aligned with corresponding pixels of the display by placing the monolithic structure on the top portion (e.g., thin film encapsulation layer) on the display.

In some implementations, the optic and the plurality of additional optics can have the same shape. For instance, the optic and the plurality of additional optics can have a shape corresponding to a dome. In alternative implementations, the optic can have a first shape and one or more of the additional optics can have a second shape that is different than the first shape. For instance, the optic positioned over the transparent region can have a cross-sectional shape corresponding to a triangle, whereas one or more of the additional optics can have a cross-sectional shape corresponding to a dome.

An electronic device according to example aspects of the present disclosure can provide numerous technical effects and benefits. For instance, the transparent region (e.g., aperture) of the display can provide a direct path between the external light and the under-display image sensor. Furthermore, the optic (e.g., micro lens) positioned over the transparent region can direct (e.g., refract) the external light into the transparent region. In this manner, the quality of images obtained via the under-display image sensor can be improved due, at least in part, to the optic directing the external light into the transparent region of the display. It should be appreciated that directing the external light into the transparent region of the display can especially improve the quality of images the under-display image sensor obtains when the display is off (that is, when the display is not displaying content).

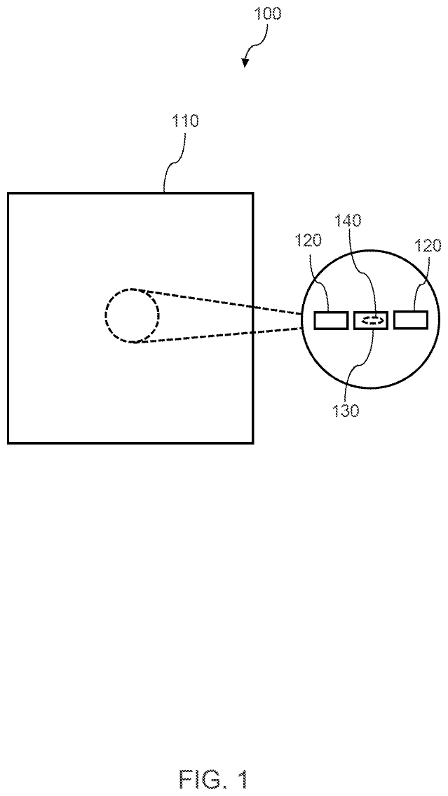

Referring now to the FIGS., FIG. 1 depicts an electronic device 100 having a display 110 according to some implementations of the present disclosure. In some implementations, the display 110 can be an organic light emitting diode display. As shown, the display 110 can include a plurality of pixels 120 (only two shown). It should be understood that the pixels 120 can be configured to output light of a plurality of different colors. In this manner, the pixels 120 of the display 110 can be controlled to display content (e.g., images, video) for viewing by a user of the electronic device 100.

In some implementations, the plurality of pixels 120 can be arranged in a row-column configuration. For instance, the display 110 can include a plurality of rows of pixels 120 and a plurality of columns of pixels 120. It should be appreciated, however, that the plurality of pixels 120 of the display 110 can be arranged in any suitable configuration.

It should be understood that the electronic device 100 can include any suitable electronic device having the display 110. For instance, in some implementations, the electronic device 100 can be a mobile computing device (e.g., smartphone, tablet, laptop, etc.).

As shown, the display 110 can define a transparent region 130 that is positioned between adjacent pixels 120. For instance, in implementations in which the pixels 120 are arranged in a row-column configuration, the transparent region 130 can be defined between adjacent pixels in a first row of the plurality of rows. More particularly, the transparent region 130 can be defined between pixels 120 in the first row that are next to one another. It should be understood that the transparent region 130 can be void of pixels 120. Details of the transparent region will be discussed below in more detail.

As shown, the electronic device 100 can include an image sensor 140 (denoted by dashed circle) positioned underneath the display 110. The image sensor 140 can be aligned with the transparent region 130 of the display 110. In this manner, the image sensor 140 can receive light exiting the transparent region 130 of the display 110. In some implementations, the image sensor 140 can include a camera configured to obtain image data (e.g., video, photos).

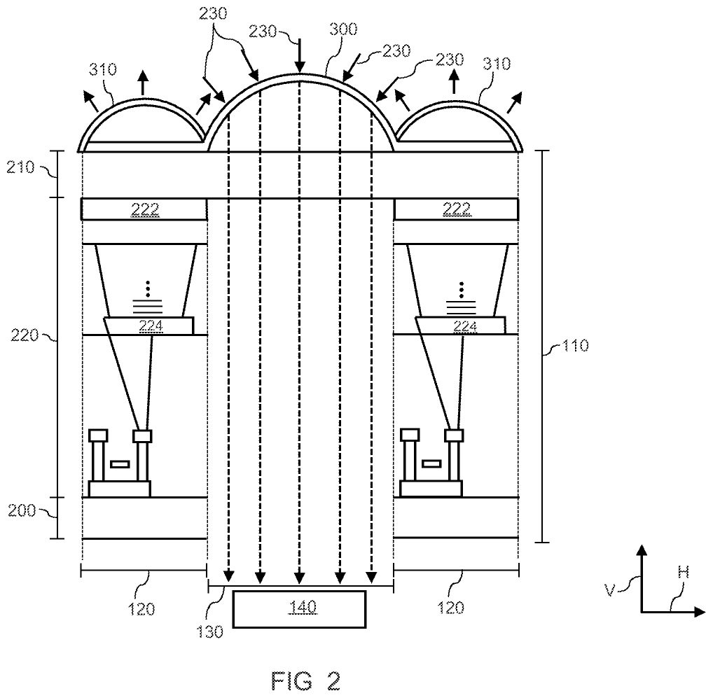

Referring now to FIG. 2, a cross-sectional view of the display 110 of the electronic device 100 (FIG. 1) is provided according to some implementations of the present disclosure. The display 110 can define a horizontal direction H and a vertical direction V. As shown, the display 110 can include a bottom portion 200, a top portion 210, and an intermediate portion 220 that is positioned between the bottom portion 200 and the top portion 210. The bottom portion 200 can include, for instance, a substrate. In some implementations, the substrate can be a flexible substrate (e.g., polyimide substrate). The top portion 210 can include a thin film encapsulation layer. In implementations in which the display 110 is an organ light emitting diode display, the thin film encapsulation layer can include a first inorganic layer, a second inorganic layer, and an organic layer positioned between the first inorganic layer and the second inorganic layer.

For locations of the display 110 that include pixels 120, the intermediate portion 220 thereof can include multiple layers. For instance, in implementations in which the display 110 is an organic light emitting diode display, the intermediate portion 220 can include a cathode 222, an anode 244, and one or more layers (e.g., emissive layer, conductive layer) positioned between the cathode 222 and the anode 224.

As shown, the transparent region 130 can be defined between the image sensor 140 and the top portion 210 of the display 110. For instance, the transparent region 130 can be an aperture extending from the image sensor 140 to the top portion 210 of the display 110 along the vertical direction V. Furthermore, the aperture can extend between adjacent pixels 120 of the display 110 along the horizontal direction H. In this manner, the transparent region 130 (e.g., aperture) can provide external light 230 (e.g., light in an environment surrounding the electronic device 100) a dedicated path to the image sensor 140 positioned underneath the display 110.

As shown, the electronic device 100 (FIG. 1) can further include an optic 300 positioned directly over the transparent region 130 of the display 110 to direct (e.g., refract) external light 230 into the transparent region 130 of the display 110. More particularly, the optic 300 can direct the external light 230 into the transparent region 130 of the display 110. In some implementations, the optic 300 can be positioned on the top portion 210 of the display 110. It should be understood that one or more parameters (e.g., shape) of the optic 300 can be configured to direct (e.g., refract) the external light 230 into the transparent region 130 of the display 110. For instance, as shown in FIG. 2, the optic 300 can have a shape corresponding to a dome. Alternatively, or additionally, the optic 300 can, in some implementations, be a micro lens (e.g., a lens having a diameter less than 1 millimeter).

In some implementations, the electronic device 100 (FIG. 1) can include a plurality of additional optics 310 (only two shown). Each of the additional optics 310 can be positioned over a corresponding pixel 120 of the display 110. Furthermore, each of the additional optics 310 can be configured to manipulate light associated with the corresponding pixel 120. For instance, each of the additional optics 310 can be configured to focus light associated with the corresponding pixel. In this manner, a “screen-door” effect associated with the display 110 can be reduced or eliminated.

In some implementations, the optic 300 positioned over the transparent region 130 of the display 110 and the additional optics 310 positioned over the corresponding pixels 120 of the display 110 can be integrally formed as a monolithic structure. In such implementations, the monolithic structure can be positioned on the top portion 210 (e.g., thin film encapsulation layer) of the display 110. In some implementations, the optic 300 and the plurality of additional optics 310 can have the same shape. For instance, the optic 300 positioned over the transparent region 130 of the display 110 and the plurality of additional optics 310 can have a shape corresponding to a dome. In alternative implementations, the optic 300 positioned over the transparent region 130 of the display 110 can have a first shape and one or more of the additional optics 300 can have a second shape that is different than the first shape.

It should be appreciated that, in some implementations, the electronic device 100 can include multiple image sensors 140. In such implementations, the display 110 of the electronic device 100 can include multiple transparent regions 130. Furthermore, the electronic device 100 can include multiple of optic 300. For instance, each of the optics 300 can be positioned over a corresponding transparent region of the multiple transparent regions 130. In this manner, external light 230 can be directed into each of the transparent regions 130 via a corresponding optic 300. It should be understood that directing the external light 230) into the transparent region 130 of the display 110 can increase the amount of external light 230 that is directed onto the image sensor 140 and thereby improve the quality of images obtained via the image sensors 140.

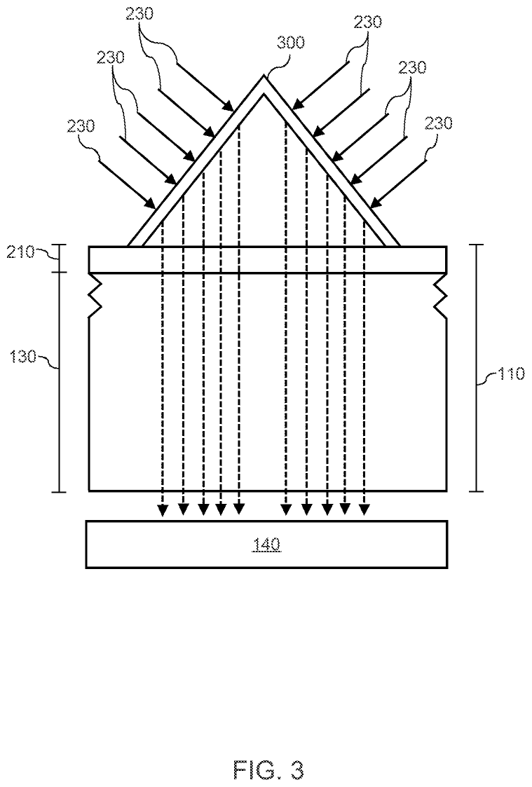

Referring now to FIG. 3, the optic 300 positioned directly over the transparent region 130 of the display 110 can, in some implementations, have a cross-sectional shape corresponding to a triangle. As shown, a first side of the optic 300 can direct the external light 230 into the transparent region 130 of the display 110. Additionally, a second side of the optic 300 can direct the external light 230 into the transparent region of the display 110. It should be understood that the optic 300 can have any suitable shape configured to facilitate directing (e.g. refracting) the external light 230 into the transparent region 130 of the display 110.

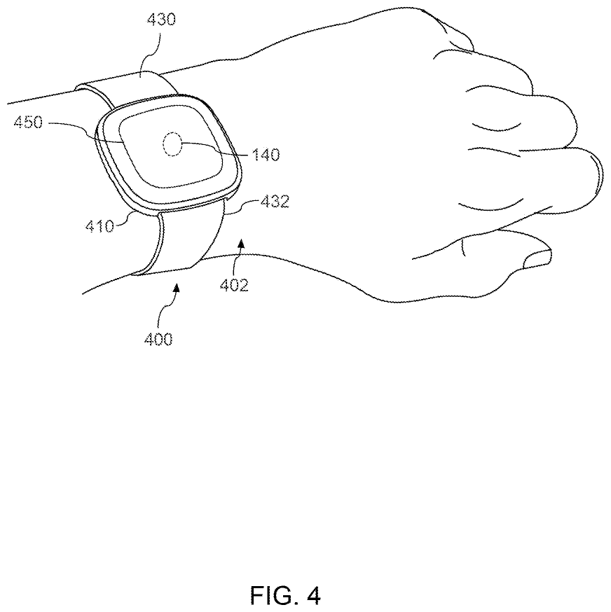

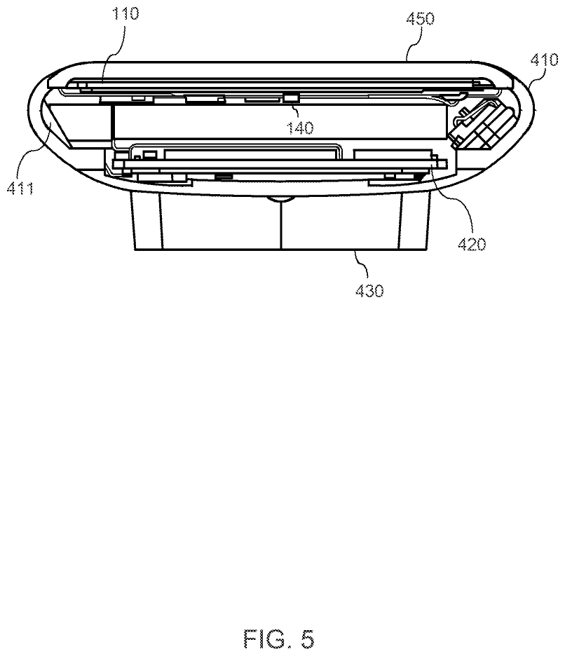

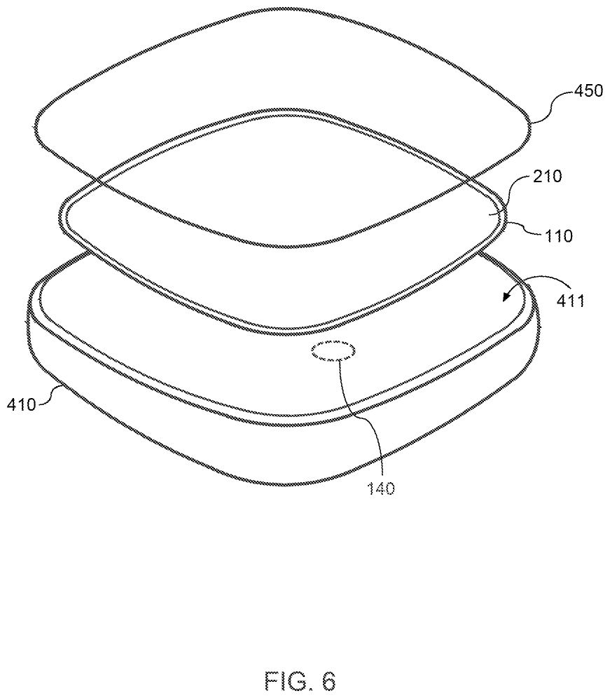

Referring now to FIGS. 4 through 6, a wearable computing device 400 is provided according to some implementations of the present disclosure. It should be understood that the wearable computing device 400 can include the display 110 of the electronic device 100 discussed above with reference to FIGS. 1 and 2. Furthermore, the wearable computing device 400 can include the image sensor 140 of the electronic device 100 discussed above with reference to FIGS. 1 and 2. Still further, the wearable computing device 400 can include the optics 300, 310 discussed above with reference to FIGS. 1 and 2. In particular, the wearable computing device 400 can include the optic 300 (FIG. 2) positioned over the transparent region 130 (FIG. 2) of the display 110. Details of the wearable computing device 400 will now be discussed.

As shown, the wearable computing device 400 can be worn, for instance, on an arm 402 (e.g., wrist) of a user. For instance, the wearable computing device 400 can include a housing 410. The housing 410 can define a cavity 411 in which one or more electronic components (e.g., disposed on printed circuit boards) are disposed. For instance, the wearable computing device 400 can include a printed circuit board 420 disposed within the cavity 411. Furthermore, one or more electronic components can be disposed on the printed circuit board 420.

The wearable computing device 400 can include a first band 430 and a second band 432. As shown, the first band 430 can be coupled to the housing 410 at a first location thereon. Conversely, the second band 432 can be coupled to the housing 410 at a second location thereon. Furthermore, the first band 430 and the second band 432 can be coupled to one another to secure the housing 410 to the arm 402 of the user.

In some implementations, the first band 430 can include a buckle or clasp (not shown). Additionally, the second band 432 can include a plurality of apertures (not shown) spaced apart from one another along a length of the second band 432. In such implementations, a prong of the buckle associated with the first band 430 can extend through one of the plurality of openings defined by the second band 432 to couple the first band 430 to the second band 432.

It should be appreciated that the first band 430 can be coupled to the second band 432 using any suitable type of fastener. For instance, in some implementations, the first band 430 and the second band 432 can include a magnet. In such implementations, the first band 430 and the second band 432 can be magnetically coupled to one another to secure the housing 410 to the arm 402 of the user.

The wearable computing device 400 can include the display 110 configured to display content (e.g., time, date, biometric, notifications, etc.) for viewing by the user. For instance, the display 110 can include a plurality of pixels. In some implementations, the display 110 can include an organic light emitting diode display. It should be understood, however, that the display 110 can include any suitable type of display.

In some implementations, the wearable computing device 400 can include a cover 450 positioned on the housing 410 so that the cover 450 is positioned on top of the display 110. In this manner, the cover 450 can protect the display 110 from being scratched. In some implementations, the wearable computing device 400 can include a seal (not shown) positioned between the housing 410 and the cover 450. For instance, a first surface of the seal can contact the housing 410 and a second surface of the seal can contact the cover 450. In this manner, the seal between the housing 410 and the cover 450 can prevent a liquid (e.g., water) from entering the cavity 411 defined by the housing 410.

It should be understood that the cover 450 can be optically transparent so that the user can view information being displayed on the display 110. For instance, in some implementations, the cover 450 can include a glass material. It should be understood, however, that the cover 450 can include any suitable optically transparent material. For instance, in some implementations, the cover 450 can include a plastic material.

While the present subject matter has been described in detail with respect to various specific example embodiments thereof, each example is provided by way of explanation, not limitation of the disclosure. Those skilled in the art, upon attaining an understanding of the foregoing, can readily produce alterations to, variations of, and equivalents to such embodiments. Accordingly, the subject disclosure does not preclude inclusion of such modifications, variations and/or additions to the present subject matter as would be readily apparent to one of ordinary skill in the art. For instance, features illustrated or described as part of one embodiment can be used with another embodiment to yield a still further embodiment. Thus, it is intended that the present disclosure cover such alterations, variations, and equivalents.

1. An electronic device comprising:
a display comprising a plurality of pixels, the display defining a transparent region positioned between a first pixel of the plurality of pixels and a second pixel of the plurality of pixels;
an image sensor positioned underneath the display, the image sensor aligned with the transparent region defined by the display; and
an optic positioned on the display and over the transparent region defined by the display, the optic configured to direct external light into the transparent region of the display.

2. The electronic device of claim 1, wherein the transparent region comprises an aperture extending from the image sensor to a top portion of the display along a vertical direction.

3. The electronic device of claim 1, wherein the plurality of pixels are arranged in a plurality of rows, and wherein the first pixel and the second pixel are next to one another in a first row of the plurality of rows.

4. The electronic device of claim 1, wherein the optic comprises a lens having a diameter of less than 1 millimeter.

5. The electronic device of claim 1, wherein the optic is disposed on a top portion of the display.

6. The electronic device of claim 5, wherein the top portion of the display comprises a thin film encapsulation layer.

7. The electronic device of claim 1, wherein a shape of the optic corresponds to a dome.

8. The electronic device of claim 1, wherein a cross-sectional shape of the optic corresponds to a triangle.

9. The electronic device of claim 1, further comprising:
a plurality of additional optics disposed on the display, each of the plurality of additional optics positioned over a corresponding pixel of the plurality of pixels.

10. The electronic device of claim 9, wherein:
the optic positioned over the transparent region of the display has a first shape; and
one or more of the plurality of additional optics has a second shape that is different from the first shape.

11. The electronic device of claim 9, wherein one or more of the additional optics comprises a lens having a diameter of less than 1 millimeter.

12. The electronic device of claim 9, wherein the optic positioned over the transparent region and the plurality of additional optics are integrally formed as a monolithic structure.

13. A wearable computing device comprising:
a housing;
a first band coupled to the housing at a first location;
a second band coupled to the housing at a second location, the second band couplable to the first band;
a display comprising a plurality of pixels, the display defining a transparent region positioned between a first pixel of the plurality of pixels and a second pixel of the plurality of pixels;
an image sensor positioned underneath the display, the image sensor aligned with the transparent region defined by the display; and
an optic positioned on the display and over the transparent region defined by the display, the optic configured to direct external light into the transparent region of the display.

14. The wearable computing device of claim 13, wherein the plurality of pixels are arranged in a plurality of rows, and wherein the first pixel and the second pixel are next to one another in a first row of the plurality of rows.

15. The wearable computing device of claim 13, wherein the optic is disposed on a top portion of the display.

16. The wearable computing device of claim 15, wherein the top portion of the display comprises a thin film encapsulation layer.

17. The wearable computing device of claim 13, further comprising:
a plurality of additional optics disposed on the display, each of the plurality of additional optics positioned over a corresponding pixel of the plurality of pixels.

18. The wearable computing device of claim 17, wherein one or more of the additional optics comprises a lens having a diameter of less than 1 millimeter.

19. The wearable computing device of claim 17, wherein the optic positioned over the transparent region of the display and the plurality of additional optics are integrally formed as a monolithic structure.

20. The wearable computing device of claim 13, wherein the transparent region comprises an aperture defined between the image sensor and a top portion of the display.
